(19) United States
(12) Patent Application Publication
(10) Pub. No.: US 2025/0323088 A1
(43) Pub. Date: Oct. 16, 2025

(54) SEMICONDUCTOR CHIP AND METHOD FOR MANUFACTURING SAME

(71) Applicant: Microchip Technology Incorporated, Chandler, AZ (US)

(72) Inventors: Shesh Mani Pandey, Gilbert, AZ (US); Yogesh Kumar Sharma, Colorado Springs, CO (US); George Dorman, Chandler, AZ (US); Randy L. Yach, Phoenix, AZ (US)

(73) Assignee: Microchip Technology Incorporated, Chandler, AZ (US)

(21) Appl. No.: 18/938,741

(22) Filed: Nov. 6, 2024

Related U.S. Application Data
(60) Provisional application No. 63/634,633, filed on Apr. 16, 2024.

(51) Int. Cl. H01L 21/76; H01L 27/06

(52) U.S. Cl. CPC H01L 21/76; H10D 84/611; H10D 84/811

(57) ABSTRACT

A semiconductor chip that may include a termination ring. An active region formed within the termination ring. A transistor formed within the active region. A diode formed within the active region.

### CROSS-REFERENCE TO RELATED APPLICATION

The present application claims priority to U.S. Provisional Patent Application No. 63/634,633, filed on Apr. 16, 2024, the contents of which are hereby incorporated by reference in their entirety.

### TECHNICAL FIELD

The present disclosure relates generally to power semiconductor devices, and more specifically to a semiconductor chip having a transistor with an integrated diode, and a method for manufacturing same.

### SUMMARY

According to an aspect of one or more examples, there is provided a semiconductor chip that may include a termination ring, an active region formed within the termination ring, a transistor formed within the active region, and a diode formed within the active region. The transistor may be connected to the diode by a common metal layer. The transistor may comprise a field effect transistor. The transistor may be a bipolar transistor. The semiconductor chip may comprise an isolation region formed within the active region, wherein the isolation region separates the transistor from the diode. The isolation region may comprise oxide, nitride or a combination of oxide and nitride.

According to an aspect of one or more examples, there is provided a semiconductor chip that may include a plurality of active regions, a termination ring surrounding each active region of the plurality of active regions, a transistor formed within one of the plurality of active regions, a diode formed within one of the plurality of active regions. The transistor may be connected to the diode by a common metal layer. The transistor may comprise a field effect transistor. The transistor may be a bipolar transistor.

According to an aspect of one or more examples, there is provided a method of manufacturing a semiconductor chip. The method may include forming a termination ring, forming an active region within the termination ring, forming a transistor within the active region, and forming a diode within the active region. The transistor may be connected to the diode by a common metal layer. The transistor may comprise a field effect transistor. The transistor may be a bipolar transistor. The method may comprise forming an isolation region within the active region, wherein the isolation region separates the transistor from the diode. The isolation region may comprise oxide, nitride or a combination of oxide and nitride.

According to an aspect of one or more examples, there is provided a method of manufacturing a semiconductor chip. The method may include forming a plurality of active regions, forming a termination ring surrounding each active region of the plurality of active regions, forming a transistor within one of the plurality of active regions; and forming a diode within one of the plurality of active regions. The transistor may be connected to the diode by a common metal layer. The transistor may comprise a field effect transistor. The transistor may be a bipolar transistor.

### BRIEF DESCRIPTION OF DRAWINGS

FIG. 1 shows a semiconductor chip according to one or more examples.

FIG. 2 shows a semiconductor chip according to one or more examples.

### DETAILED DESCRIPTION OF VARIOUS EXAMPLES

Reference will now be made in detail to the following various examples, which are illustrated in the accompanying drawings, wherein like reference numerals refer to like elements throughout. The following examples may be embodied in various forms without being limited to the examples set forth herein.

Wiring a semiconductor chip to another semiconductor chip may result in failures, switching losses, and additional expense. Therefore, there is a need for a semiconductor chip that reduces the need for wiring chips to one another.

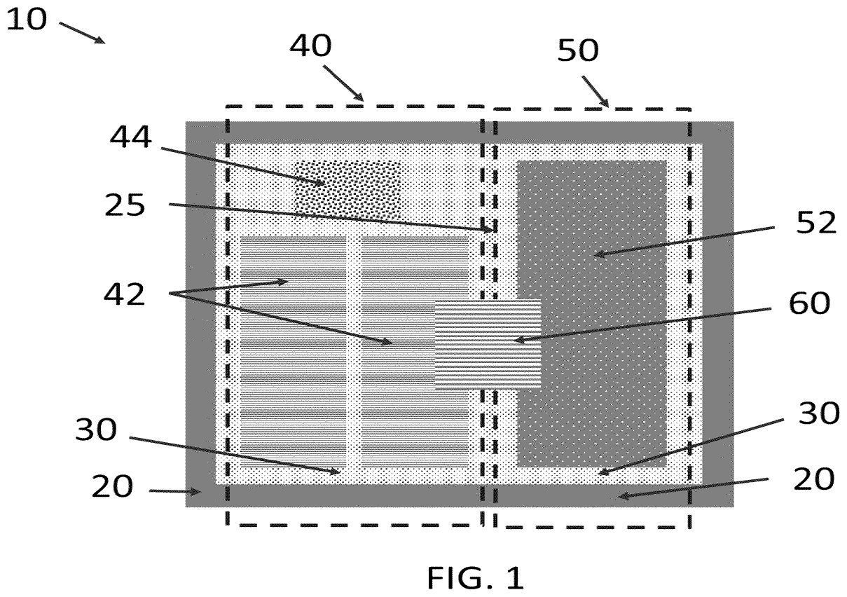

FIG. 1 shows a semiconductor chip 10 according to one or more examples. The semiconductor chip 10 shown in FIG. 1 may include a termination ring 20 surrounding an active region 30. Any type of device, any size of device and any number of devices may be manufactured into the active region 30 of the semiconductor chip 10. In FIG. 1, the example semiconductor chip 10 may include a transistor 40 and a diode 50. The transistor 40 shown in FIG. 1 may comprise two sources 42 and a gate 44 within the active region 30 within the termination ring 20 of the semiconductor chip 10. The diode 50 shown in FIG. 1 may comprise an anode 52 within the active region 30 within the termination ring 20 of the semiconductor chip 10. The arrangement of the devices in the semiconductor chip 10 as shown in FIG. 1 reduces the need to wire bond a diode 50 to a transistor 40 thereby reducing wire bonding failures. In addition, the semiconductor chip 10 as shown in FIG. 1 reduces the area needed for two devices (diode 50 and transistor 40). In FIG. 1, the example semiconductor chip 10 may include an isolation region 25 that may separate the active region 30 for the transistor 40 from the active region 30 for the diode 50. The isolation region 25 may comprise oxide, nitride or a combination of oxide and nitride. The termination ring 20 may comprise a mesa structure, guard rings, field plates, high resistivity region by ion implantation, or a combination thereof. In FIG. 1, the example semiconductor chip 10 may include connecting the diode 50 to the transistor 40 by a common metal layer 60. This connection of the diode 50 to the transistor may be made during the fabrication of the semiconductor chip 10. The gate 44 and the source(s) 42 of the transistor 40 may be part of a field effect transistor 40, a bipolar transistor 40 and/or any other transistor 40.

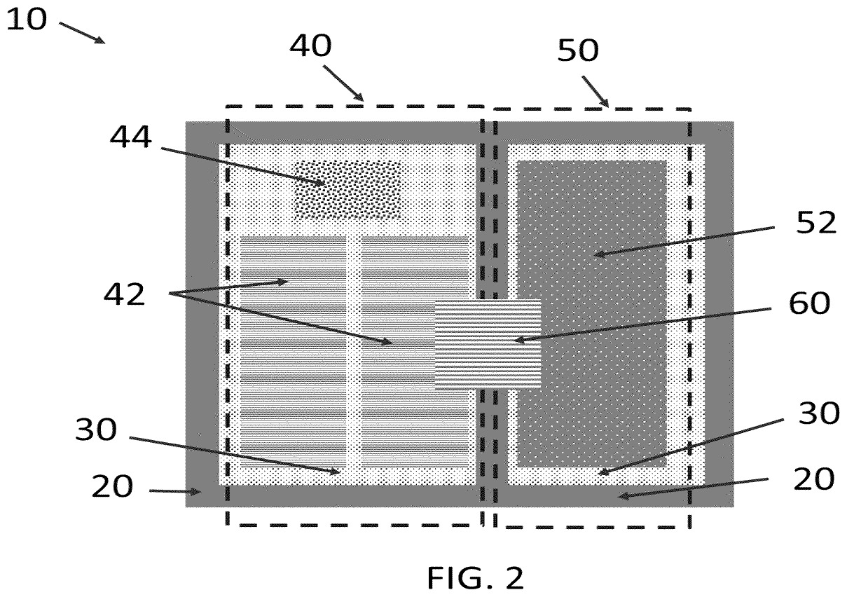

FIG. 2 shows a semiconductor chip 10 according to one or more examples. The semiconductor chip 10 shown in FIG. 2 may include a plurality of active regions 30. In FIG. 2, the example semiconductor chip 10 may include a termination ring 20 surrounding each active region 30 of the plurality of active regions 30. Any type of device, any size of device and any number of devices may be manufactured into the plurality of active regions 30 of the semiconductor chip 10. In FIG. 2, the example semiconductor chip 10 may include a transistor 40 and a diode 50. The transistor 40 shown in FIG. 2 may comprise two sources 42 and a gate 44 within the active region 30 within the termination ring 20 of the semiconductor chip 10. The diode 50 shown in FIG. 2 may comprise an anode 52 within the active region 30 within the termination ring 20 of the semiconductor chip 10. The arrangement of the devices of the semiconductor chip 10 as shown in FIG. 2 reduces the need to wire bond a diode 50 to a transistor 40 thereby reducing wire bonding failures. In addition, the semiconductor chip 10 as shown in FIG. 2 reduces the area needed for two devices (diode 50 and transistor 40). The termination ring 20 may comprise a mesa structure, guard rings, field plates, high resistivity region by ion implantation, or a combination thereof. In FIG. 2, the example semiconductor chip 10 may include connecting the diode 50 to the transistor 40 by a common metal layer 60. This connection of the diode 50 to the transistor may be made during the fabrication of the semiconductor chip 10. The gate 44 and the source(s) 42 of the transistor 40 may be part of a field effect transistor 40, a bipolar transistor 40 and/or any other transistor 40.

The present invention for manufacturing a semiconductor chip may be fabricated by forming a termination ring 20. The example method may include forming an active region 30 within the termination ring 20 for the devices to be included in the semiconductor chip 10. Any type of device, any size of device and any number of devices may be manufactured into the active region 30 of the semiconductor chip 10. The example method may include forming a transistor 40 within the active region 30. The transistor 40 of the example method may comprise forming two sources 42 and a gate 44 within the active region 30 within the termination ring 20 of the semiconductor chip 10. The example method may include forming a diode 50 within the active region 30. The diode 50 may comprise forming an anode 52 within the active region 30 within the termination ring 20 of the semiconductor chip 10. The arrangement of the present invention of the semiconductor chip 10 of the example method reduces the need to wire bond a diode 50 to a transistor 40 thereby reducing wire bonding failures. In addition, the semiconductor chip 10 of the example method reduces the area needed for two devices (diode 50 and transistor 40). The example method may include forming an isolation region 25 that may separate the active region 30 for the transistor 40 from the active region 30 for the diode 50. The isolation region 25 may comprise oxide, nitride or a combination of oxide and nitride. The termination ring 20 may comprise a mesa structure, guard rings, field plates, high resistivity region by ion implantation, or a combination thereof. The example method may include connecting the diode 50 to the transistor 40 by a common metal layer 60. This connection of the diode 50 to the transistor may be made during the fabrication of the semiconductor chip 10. The gate 44 and the source(s) 42 of the transistor 40 may be part of a field effect transistor 40, a bipolar transistor 40 and/or any other transistor 40.

The present invention for manufacturing a semiconductor chip may be fabricated by forming a plurality of active regions 30 for the devices to be included in the semiconductor chip 10. Any type of device, any size of device and any number of devices may be manufactured into the plurality of active regions 30 of the semiconductor chip 10. The example method may include forming a termination ring 20 surrounding each active region of the plurality of active regions 30. The example method may include forming a transistor 40 within one of the plurality of active regions 30. The transistor 40 of the example method may comprise forming two sources 42 and a gate 44 within one of the plurality of active regions 30 within the termination ring 20 of the semiconductor chip 10. The example method may include forming a diode 50 within one of the plurality of active regions 30. The diode 50 may comprise forming an anode 52 within one of the plurality of active regions 30 within the termination ring 20 of the semiconductor chip 10. The arrangement of the present invention of the semiconductor chip 10 of the example method reduces the need to wire bond a diode 50 to a transistor 40 thereby reducing wire bonding failures. In addition, the semiconductor chip 10 of the example method reduces the area needed for two devices (diode 50 and transistor 40). The termination ring 20 may comprise a mesa structure, guard rings, field plates, high resistivity region by ion implantation, or a combination thereof. The example method may include connecting the diode 50 to the transistor 40 by a common metal layer 60. This connection of the diode 50 to the transistor may be made during the fabrication of the semiconductor chip 10. The gate 44 and the source(s) 42 of the transistor 40 may be part of a field effect transistor 40, a bipolar transistor 40 and/or any other transistor 40.

Various examples have been disclosed herein, in connection with the above description and the drawings. It will be understood that it would be unduly repetitious to literally describe and illustrate every combination and subcombination of these examples. Accordingly, all examples may be combined in any way and/or combination, and the present specification, including the drawings, shall be construed to constitute a complete written description of all combinations and subcombinations of the examples described herein, and of the manner and process of making and using them, and shall support claims to any such combination or subcombination.

It will be appreciated by persons skilled in the art that the examples described herein are not limited to what has been particularly shown and described herein above. In addition, unless mention was made above to the contrary, it should be noted that all of the accompanying drawings are not to scale. A variety of modifications and variations are possible in light of the above teachings.

What is claimed is:

1. A semiconductor chip comprising:
a termination ring;
an active region formed within the termination ring;
a transistor formed within the active region; and
a diode formed within the active region.

2. The semiconductor chip of claim 1, wherein the transistor is connected to the diode by a common metal layer.

3. The semiconductor chip of claim 1, wherein the transistor comprises a field effect transistor.

4. The semiconductor chip of claim 1, wherein the transistor comprises a bipolar transistor.

5. The semiconductor chip of claim 1, comprises an isolation region formed within the active region, the isolation region separates the transistor from the diode.

6. The semiconductor chip of claim 5, wherein the isolation region comprises oxide, nitride or a combination of oxide and nitride.

7. A semiconductor chip comprising:
a plurality of active regions;
a termination ring surrounding each active region of the plurality of active regions;
a transistor formed within one of the plurality of active regions; and
a diode formed within one of the plurality of active regions.

8. The semiconductor chip of claim 7, wherein the transistor is connected to the diode by a common metal layer.

9. The semiconductor chip of claim 7, wherein the transistor comprises a field effect transistor.

10. The semiconductor chip of claim 7, wherein the transistor comprises a bipolar transistor.

11. A method of manufacturing a semiconductor chip, the method comprising:
forming a termination ring;
forming an active region within the termination ring;
forming a transistor within the active region; and
forming a diode within the active region.

12. The method of claim 11, wherein the transistor is connected to the diode by a common metal layer.

13. The method of claim 11, wherein the transistor comprises a field effect transistor.

14. The method of claim 11, wherein the transistor comprises a bipolar transistor.

15. The method of claim 11, comprises forming an isolation region within the active region, the isolation region separating the transistor from the diode.

16. The method of claim 15, wherein the isolation region comprises oxide, nitride or a combination of oxide and nitride.

17. A method of manufacturing a semiconductor chip, the method comprising:
forming a plurality of active regions;
forming a termination ring surrounding each active region of the plurality of active regions;
forming a transistor within one of the plurality of active regions; and
forming a diode within one of the plurality of active regions.

18. The method of claim 17, wherein the transistor is connected to the diode by a common metal layer.

19. The method of claim 17, wherein the transistor comprises a field effect transistor.

20. The method of claim 17, wherein the transistor comprises a bipolar transistor.
